(19) United States
(12) Patent Application Publication
(10) Pub. No.: US 2010/0171173 A1
(43) Pub. Date: Jul. 8, 2010

(54) TRENCH MOSFET WITH IMPROVED SOURCE-BODY CONTACT

(75) Inventor: FU-YUAN HSIEH, HsinChu (TW)

Correspondence Address: BAYSHORE PATENT GROUP, LLC, 520 CHANTECLER DR., FREMONT, CA, 94539, US

(73) Assignee: FORCE MOS TECHNOLOGY CO. LTD., HsinChu (TW)

(21) Appl. No.: 12/350,904

(22) Filed: Jan. 8, 2009

(51) Int. Cl. H01L 29/78; H01L 29/768; H01L 21/8238; H01L 21/04; H01L 21/336; H01L 29/06

(52) U.S. Cl. 257/333; 257/334; 438/272; 257/E21.419; 257/E21.41; 257/E29.028

(57) ABSTRACT

A trench MOSFET with improved source-body contact structure is disclosed. The improved contact structure can enlarge the P+ area below to wrap the sidewalls and bottom of source-body contact within P-body region to further enhance the avalanche capability. On the other hand, one of the embodiments disclosed a wider tungsten plug structure to connect source metal, which helps to further reduce the source contact resistance.

### FIELD OF THE INVENTION

This invention relates generally to the cell structure and fabrication process of power semiconductor devices. More particularly, this invention relates to a novel and improved cell structure and improved process for fabricating a trench MOSFET with improved source contact structure.

### BACKGROUND OF THE INVENTION

Please refer to FIG. 1 for a cell structure of MOSFET of prior art (U.S. patent application Ser. No. 6,888,196) with conventional source-body contact structure. The trench MOSFET is formed on an N+ substrate 900 on which an N doped epitaxial layer 902 is grown. Inside said epitaxial layer 902, a plurality of trenches 910a (not shown) are etched and filled with N+ doped poly within trenches to serve as trench gates 910 over a gate oxide layer 908. Between each trench, there is a P-body region 912 introduced by Ion Implantation, and n+source regions 914 near the top surface of said P-body area. Said source regions and body regions are connected to source metal 920 via trench source-body contact 916 through a layer of thick contact oxide 918. Around the bottom of each trench source-body contact 916, an area of heavily P+ doped 906 is formed to reduce the resistance between source and body region. Metal layer 920 serving as source metal is deposited on the front surface of whole device while metal layer 922 serving as drain metal deposited on the rear side of substrate 900. What should be noticed is that, the P+ area 906 underneath trench source-body contact bottom is formed by BF2 Ion Implantation before source-body contact trench's filled with contact material. As the sidewalls of source-body contact trench is perpendicular to the front surface of epitaxial layer, said P+ area can be implanted only around the bottom of source-body contact trench no matter with or without contact oxide BF2 Ion Implantation, resulting a high resistance Rp underneath n+ source and between channel and P+ area. As is known to all, a parasitic n+/P/N will be turned on if Iav*Rp>0.7V where Iav is avalanche current originated from the trench bottom. Therefore, the conventional vertical source contact shown in FIG. 1 has a poor avalanche capability which significantly affects the performance of whole device.

Another source-body contact structure with BF2 Ion Implantation through a screen oxide deposited after contact Si etch is proposed in that application to avoid the BF2 Ion implantation into n+ contact sidewall causing higher n+ contact resistance, as shown in FIG. 2. The structure here is almost the same as structure in FIG. 1 except for the slope source-body contact trench. However, it is still not enough to resolve the high Pp problem as the P+ area is also existed only around the bottom of source contact. At the same time, a same structure without the screen oxide BF2 Ion Implantation of prior art is given in FIG. 3. As only the source contact hole is implanted with BF2 Ion, the P+ area is apparently enlarged, resolving the high Rp issue discussed above. However, another problem is thus introduced, which is that the N+ concentration on contact trench sidewalls will be reduced as a result of larger BF2 Ion Implantation area, causing high source contact resistance.

Accordingly, it would be desirable to provide a trench MOSFET cell with improved source contact structure to avoid those problems mentioned above.

### SUMMARY OF THE INVENTION

It is therefore an object of the present invention to provide new and improved trench MOSFET cell and manufacture process to enhance the avalanche capability and to reduce the contact resistance caused by BF2 Ion Implantation on n+ portion along source contact trench sidewalls.

One aspect of the present invention is that as shown in FIG. 4, an improved source-body contact structure is proposed, which has vertical contact trench sidewalls within n+ source region, and has slope contact trench sidewalls within P-body region. To be detailed, the contact trench sidewalls are substantially vertical (90±5 degree) within n+ source regions, and the taper angle is less than 85 degree respect to top surface of epitaxial layer within P-body region, as illustrated in FIG. 6C. By employing this structure, the P+ area can be enlarged to wrapping the bottom and the slope sidewalls of source-body contact trench in P-body region no matter implanting whole device surface or only the source-body contact hole, which resolves the high Rp problem and enhances the avalanche capability. On the other hand, there will be no or insignificant BF2 Ion Implantation on sidewalls adjacent to n+ source regions even if only source contact hole is implanted, avoiding the N+ concentration reduction issue occurs in FIG. 3, thus preventing the increasing of source contact resistance from happening.

Another aspect of the present invention is that, in another embodiment, the source-body contact width within insulating layer under source metal is designed to be larger to further reduce the source contact resistance between tungsten plug and source metal as a larger connection area is offered as shown in FIG. 5.

Briefly, in a preferred embodiment, as shown in FIG. 4, the present invention disclosed a trench MOSFET cell comprising: an N+ doped substrate with a layer of Ti/Ni/Ag on the rear side serving as drain metal; a lighter N doped epitaxial layer grown on said substrate; a plurality of trenches etched into said eptaxial layer as gate trenches; a gate oxide layer on the front surface of epitaxial layer and along the inner surface of said gate trenches; doped poly filled within said gate trenches to form trench gates; P-body regions extending between every two trench gates; source regions near the top surface of P-body regions; a thick contact oxide layer onto front surface of epitaxial layer; source-body contact trench penetrating through said contact oxide layer, said gate oxide layer and said n+ source region with vertical sidewalls while into P-body region with slope sidewalls; P+ area wrapping the slope sidewalls and bottom of source-body contact trench to enhance avalanche capability; metal Ti/TiN/W or Co/TiN/W refilled into source-body contact trench acting as source-body contact metal; metal Al Alloys deposited onto whole device serving as source metal.

Briefly, in another preferred embodiment, as shown in FIG. 5, the trench MOSFET disclosed has the same structure with that of the first embodiment except that, there is an additional PSG or BPSG layer on contact oxide layer, and the width of source-body contact within PSG or BPSG layer is larger than that within contact oxide layer and n+ source region. With a wider tungsten plug filling in source-body contact trench, this structure helps to further reduce source contact resistance between tungsten plug and source metal.

This invention further discloses a method for manufacturing a trench MOSFET cell comprising a step of forming said MOSFET cell with trench gates surrounded by a source region encompassed in a body region above a drain region disposed on a bottom surface of an N+ substrate. In a preferred embodiment, the method further comprises methods of forming a source-body contact with vertical sidewalls within thick contact oxide, gate oxide and n+ source region while with slope sidewalls in P-body region. In another preferred embodiment, the method further comprises methods of forming a source-body contact with vertical sidewalls within PSG or BPSG layer, contact oxide layer, gate oxide layer and n+ source regions while with slope sidewalls in P-body regions, more important, the width of source-body contact in PSG or BPSG is wider than that in contact oxide to further reduce contact resistance between tungsten plug and source metal.

These and other objects and advantages of the present invention will no doubt become obvious to those of ordinary skill in the art after having read the following detailed description of the preferred embodiment, which is illustrated in the various drawing figures.

### BRIEF DESCRIPTION OF THE DRAWINGS

The present invention can be more fully understood by reading the following detailed description of the preferred embodiments, with reference made to the accompanying drawings, wherein:

FIG. 1 is a side cross-sectional view of a trench MOSFET cell of prior art.

FIG. 2 is a side cross-sectional view of another trench MOSFET cell of prior art.

FIG. 3 is a side cross-sectional view of another trench MOSFET cell of prior art.

FIG. 4 is a side cross-sectional view of an embodiment for the present invention.

FIG. 5 is a side cross-sectional view of another embodiment for the present invention.

FIG. 6A to 6F are a serial of side cross sectional views for showing the processing steps for fabricating trench MOSFET cell in FIG. 4.

FIG. 7 is a side cross-sectional view to show the process step for fabricating trench MOSFET cell in FIG. 5.

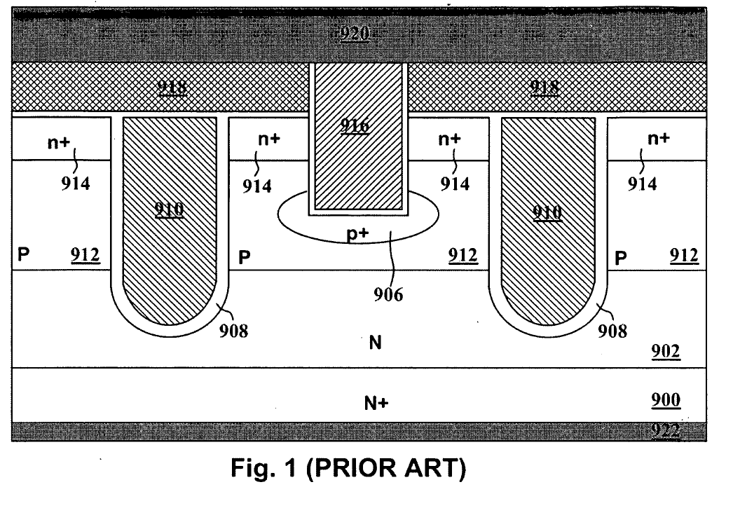

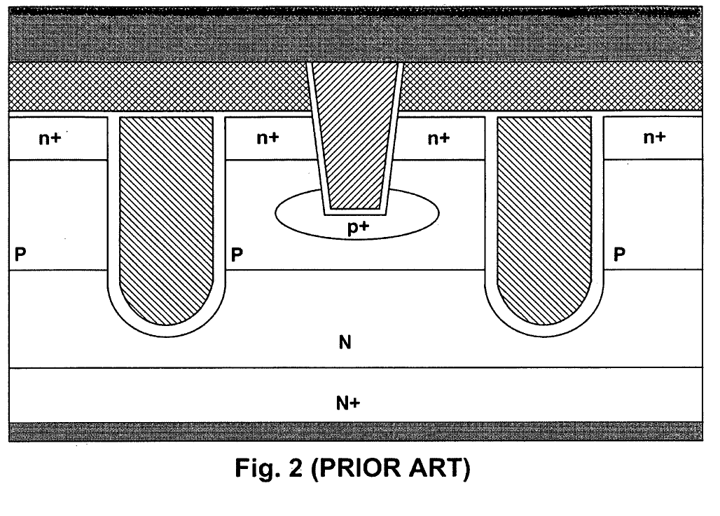

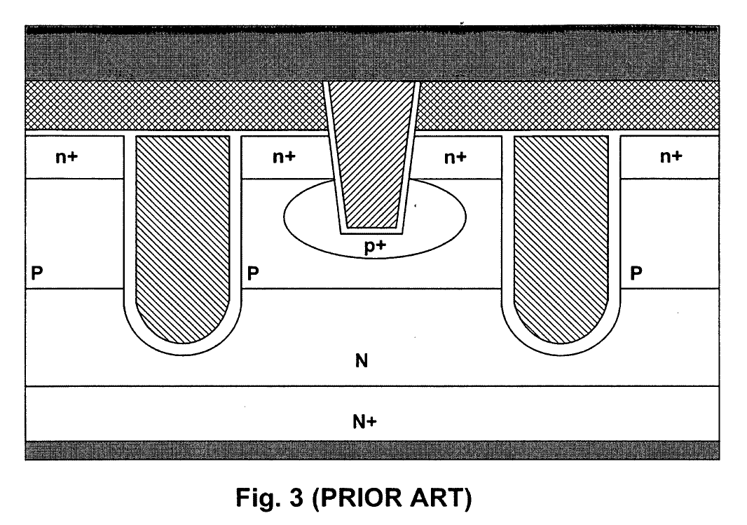

### DETAILED DESCRIPTION OF THE EMBODIMENTS

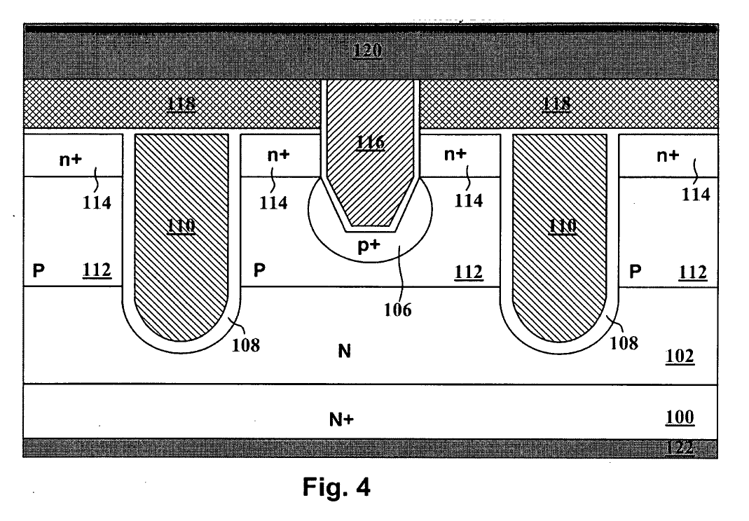

Please refer to FIG. 4 for a preferred embodiment of the present invention. The shown trench MOSFET cell is formed on an N+ substrate 100 coated with back metal Ti/Ni/Ag on rear side as drain. Onto said substrate 100, grown an N epitaxial layer 102, and a plurality of trenches 110a (not shown) were etched wherein. To fill these trenches, doped poly was deposited into trenches 110a (not shown) above gate oxide layer 108 to form trench gates 110. P-body regions 112 are extending between trenches gates 110 with a layer of source regions 114 near the top surface of P-body regions 112. Source-body contact trench 116a (not shown) is etched through thick contact oxide 118 and n+ source region 114, and into P-body region 112. Especially, the sidewalls of source-body contact trench are perpendicular to the front surface of epitaxial layer within contact oxide 118 and n+ source region 114 while is oblique within P-body region 112 with a taper angle less than 85 degree. Underneath source-body contact 116 formed with Ti/TiN/W or Co/TiN/W, a heavily P+ doped area 106 is formed wrapping the slope trench and bottom in P-body region 112 to reduce the resistance between source and body and thus enhance the avalanche capability. Above thick contact oxide 118, source metal 120 is deposited to be electrically connected to source region 114 and body region 112 via source-body contact 116.

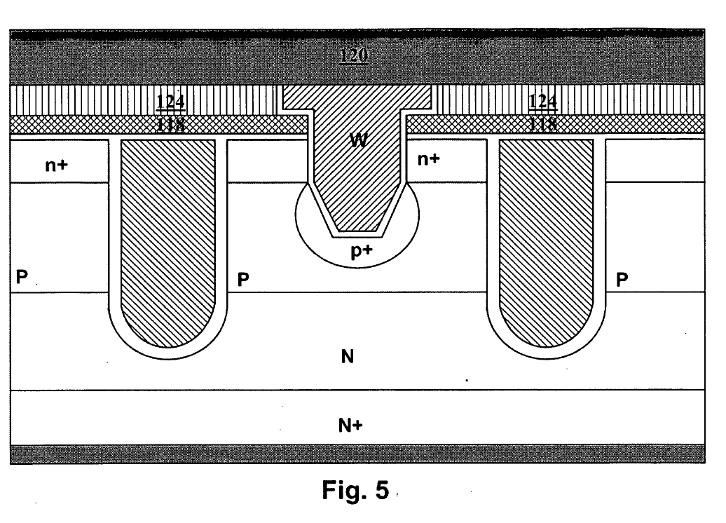

FIG. 5 shows another preferred embodiment of the present invention. Compared to FIG. 4, the structure in FIG. 5 has a different source-body contact structure with an additional PSG or BPSG layer 124 between source metal layer 120 and contact oxide layer 118. See FIG. 5, within PSG or BPSG layer 124, the width of source-body contact is wider, which is helpful to offer a wider tungsten plug area to connect source metal and result in a lower contact resistance between tungsten plug and source metal.

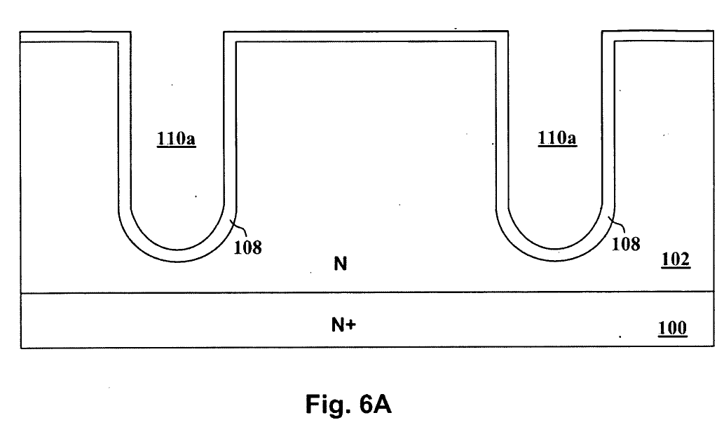

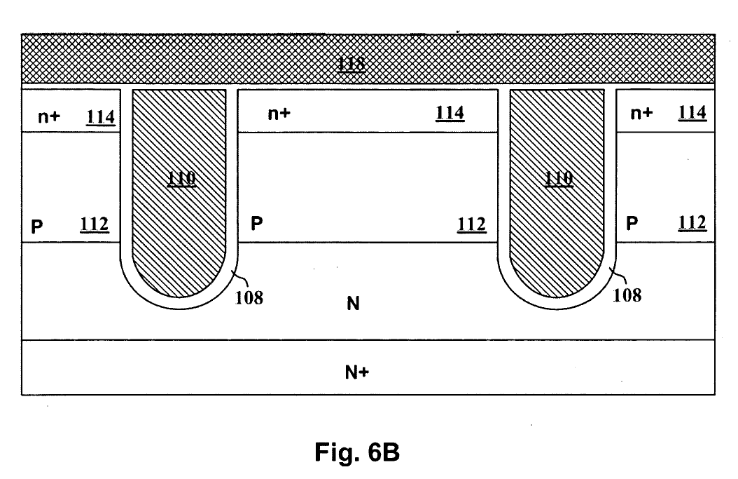

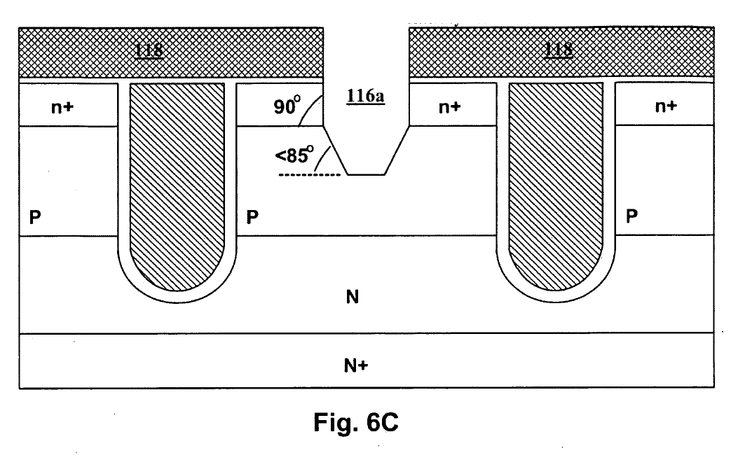

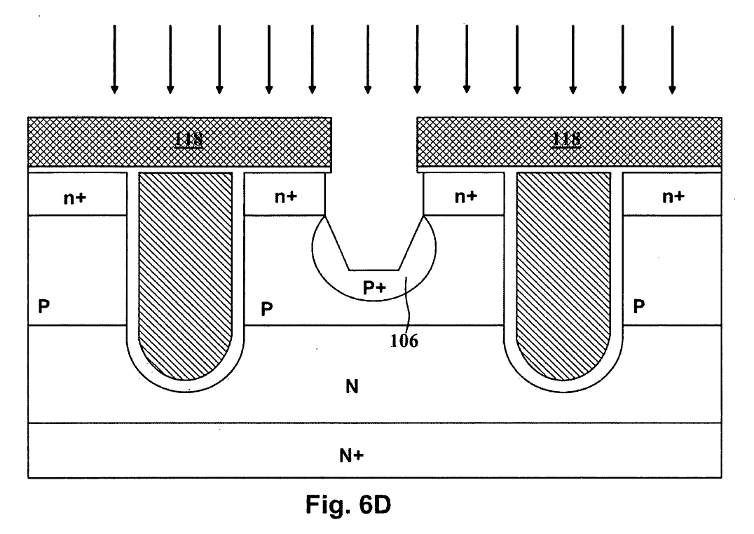

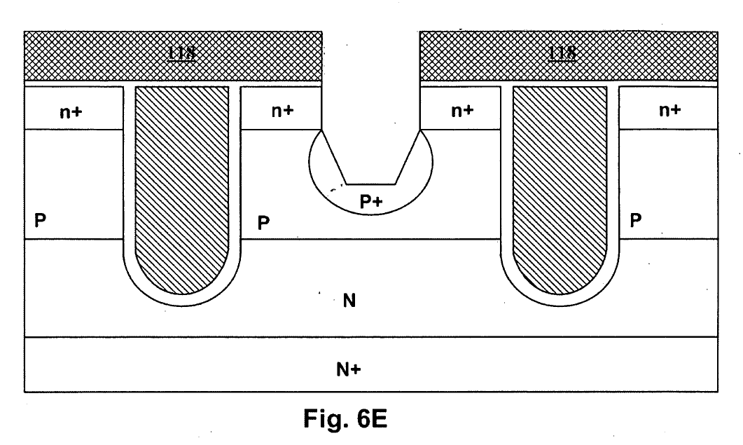

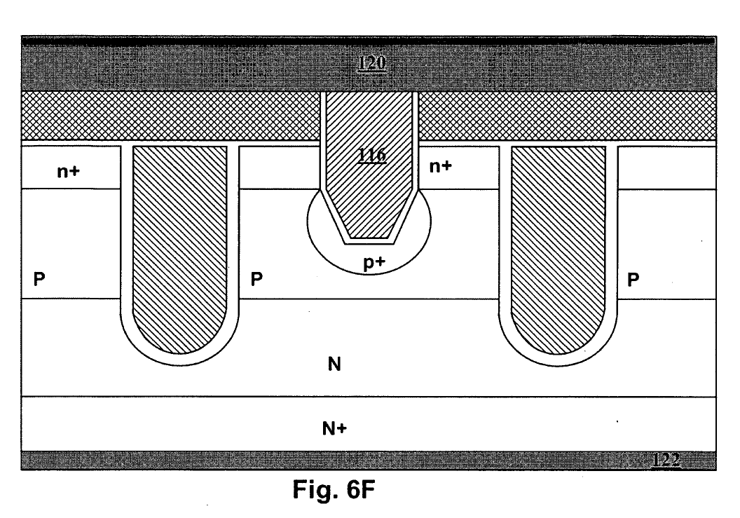

FIGS. 6A to 6F show a series of exemplary steps that are performed to form the inventive trench MOSFET of the present invention shown in FIG. 4. In FIG. 6A, an N-doped epitaxial layer 102 is grown on an N+ substrate 100, then, a trench mask (not shown) is applied, which is then conventionally exposed and patterned to leave mask portions. The patterned mask portions define the gate trenches 110a, which are dry silicon etched through mask opening to a certain depth. A sacrificial oxide is deposited and then removed to eliminate the plasma damage may introduced during trenches etching process. After the trench mask removal, a gate oxide 108 is deposited on the front surface of epitaxial layer and the inner surface of gate trenches 110a. In FIG. 6B, all gate trenches 110a are filled with doped poly to form trench gates 110. Then, the filling-in material is etched back or CMP (Chemical Mechanical Polishing) to expose the portion of gate oxide layer that extends over the surface of epitaxial layer. Next, an Ion Implantation is applied to form P-body regions 112, followed by a P-body diffusion step for P-body region drive in. After that, another Ion Implantation is applied to form n+ source regions 114, followed by an n+ diffusion step for source regions drive in. Then, the process continues with the deposition of thick contact oxide layer 118 over entire structure.

In FIG. 6C, a source-body contact mask (not shown) is applied to carry out the source-body contact etch to open the source-body contact trench 116a by successive dry oxide etching and dry silicon etching. When etching through the oxide layer and n+ source region, sidewalls of source-body contact trench 116a are substantially vertical (90±5 degree) while etching into P-body regions, sidewalls of source-body contact trench 116a has taper angle (less than 85 degree) respect to top surface of epitaxial layer, as shown in FIG. 6C. In FIG. 6D, down stream silicon etch is employed to remove the sidewalls' damage introduced during dry silicon etch, which also creates undercut of silicon to prevent the n+ sidewalls from followed BF2 Ion Implantation for reducing source contact resistance. Then, the BF2 Ion Implantation is carried out over entire surface or only above source-body contact trench to form the P+ area wrapping the sidewalls and bottom of source-body contact trench within P-body region to further enhance avalanche capability. In FIG. 6E, a pre-Ti/TiN cleaning step is performed with dilute HF to remove the oxide layer over-hanged the inner surface of source contact trench. In FIG. 6F, source-body contact trench 116a is filled with Ti/TiN/W or Co/TiN/W by a Ti/TiN/W or Co/TiN/W deposition. Then, W and Ti/TiN or Co/TiN etching back is performed to form source-body contact 116. After that, metal layer is deposited on the front and rear surface of device to serve as source metal 120 and drain metal 122, respectively.

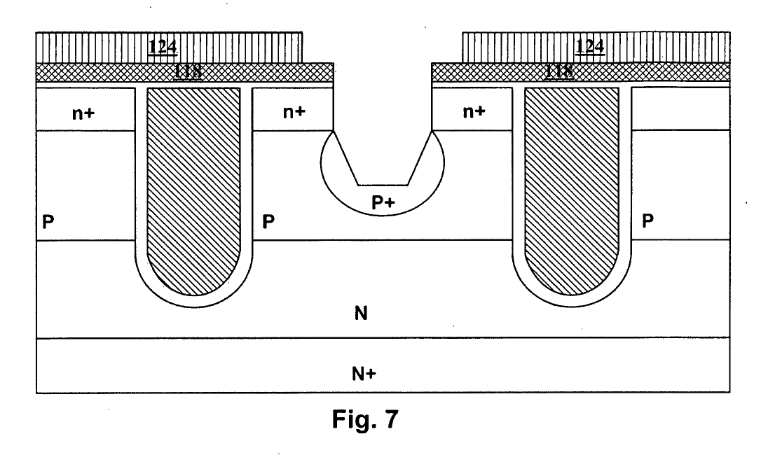

FIG. 7 shows the difference when forming source-body contact between structure in FIG. 4 and FIG. 5. Until the formation of contact oxide 118, the steps are the same with those shown in FIG. 6A to FIG. 6B. Here, above the contact oxide 118, an additional PSG or BPSG layer 124 is deposited. When etching the source-body contact trench, the trench width in layer 124 is wider than that in other portions, which will offer a larger metal connection area to further reduce the source contact resistance.

Although the present invention has been described in terms of the presently preferred embodiments, it is to be understood that such disclosure is not to be interpreted as limiting. Various alternations and modifications will no doubt become apparent to those skilled in the art after reading the above disclosure. Accordingly, it is intended that the appended claims be interpreted as covering all alternations and modifications as fall within the true spirit and scope of the invention.

What is claimed is:

1. A vertical semiconductor power MOS device comprising a plurality of semiconductor power cells with each cell comprising a plurality of trench gates surrounded by a plurality of source regions above a plurality of body regions above a drain region disposed on a bottom surface of a substrate, wherein said trench MOSFET further comprising:
a substrate of a first type conductivity;
an epitaxial layer of said first type conductivity over said substrate, having a lower doping concentration than said substrate;
a plurality of trenches extending into said epitaxial layer, surrounded by a plurality of source regions of said type conductivity above said body regions of the second type conductivity;
a first insulating layer lining said trenches as gate dielectric;
a doped polysilicon of the first type conductivity as gate regions overlying said insulating layer;
a second insulating layer disposed over said epitaxial layer to isolate source metal which contacts to said both source and body region, from said doped polysilicon as said gate regions;
a plurality of source-body contact trenches opened with sidewalls substantially perpendicular to a top epitaxial surface within said source regions and with tapered sidewalls respect to said top surface into said body regions;
a front metal disposed on front surface of device as source metal; and
a backside metal disposed on backside of said substrate as drain metal.

2. The trench MOSFET of claim 1, wherein the angle between said source-body contact trench sidewalls and said top surface is 90±5 degree within said source regions and is less than 85 degree within said body regions.

3. The trench MOSFET of claim 1, wherein said second insulating layer is SRO (Silicon Rich Oxide).

4. The trench MOSFET of claim 1, wherein said second insulating layer is combination of SRO and PSG or BPSG to further reduce source contact resistance.

5. The trench MOSFET of claim 1, wherein said source-body contact trenches are filled with Ti/TiN/W.

6. The trench MOSFET of claim 1, wherein said source-body contact trenches are filled with Co/TiN/W.

7. The trench MOSFET of claim 1, wherein said source-body contact trenches are filled with Ti/TiN/Al alloys.

8. The trench MOSFET of claim 1, wherein said source metal is Al alloys, Ti/Al alloys, Ti/TiN/Al alloys, Ti/Ni/Ag or Cu.

9. A method for manufacturing a trench MOSFET with improved source contact structure comprising the steps of:
growing an epitaxial layer upon a heavily N doped substrate, wherein said epitaxial layer is doped with a first type dopant, eg., N dopant;
forming a trench mask with open and closed areas on the surface of said epitaxial layer;
removing semiconductor material from exposed areas of said trench mask to form a plurality of gate trenches;
depositing a sacrificial oxide layer onto the surface of said trenches to remove the plasma damage introduced during opening said trenches;
removing said sacrificial oxide and said trench mask;
depositing a first insulating layer on the surface of said epitaxial layer and along the inner surface of said gate trenches as gate oxide;
depositing doped poly or combination of doped poly and undoped poly onto said gate oxide and into said gate trenches;
etching back or CMP said doped poly from the surface of said gate oxide and leaving enough doped poly into said gate trenches to serve as trench gate material;
forming silicide on top poly as alternative for low Rg;
implanting said epitaxial layer with a second type dopant to from P-body regions;
implanting whole device with a first type dopant to form source regions;
forming a second insulating layer onto whole surface;
forming a contact mask on the surface of said second insulating layer and removing insulating material and semiconductor material;
implanting BF2 ion to form P+ area wrapping sidewalls and bottom of source-body contact trench within P-body reigon;
cleaning oxide along the inner surface of source-body contact trench with dilute HF as pre-Ti/TiN clean;
depositing Ti/TiN/W or Co/TiN/W consequently into source-body contact trenches and on the front surface;
etching back W and Ti/Tin or Co/TiN to form source-body contact metal plug and depositing a layer of Al alloys on the front and rear side of device, respectively.

10. The method of claim 9, wherein forming said gate trenches comprises etching said epitaxial layer according to the open areas of said trench mask by dry silicon etching.

11. The method of claim 9, wherein forming said P-body regions comprises a step of diffusion to achieve a certain depth after P-body implantation step.

12. The method of claim 9, wherein forming said source regions comprises a step of diffusion to achieve a certain depth after n+ Ion Implantation step.

13. The method of claim 9, wherein said second insulating layer is SRO or combination of SRO and PSG or BPSG.

14. The method of claim 9, wherein forming said source-body contact trench comprises etching through said SRO layer and gate oxide layer by dry oxide etching according to the exposed areas of said contact mask.

15. The method of claim 9, wherein forming said source-body contact trench comprises etching through PSG or BPSG layer with a larger width, etching through SRO and gate oxide layer with a smaller width.

16. The method of claim 9, wherein forming said source-body contact trench comprises etching through said n+ source regions and into said P-body regions by dry silicon etching according to the exposed areas of said contact mask.

17. The method of claim 9, wherein implanting BF2 ion to form P+ area comprises implanting BF2 ion above source-body contact trench as well as above the second insulating layer.

18. The method of claim 9, wherein implanting BF2 ion to form P+ area comprises implanting BF2 ion only above source-body contact trench.
